(19) United States
(12) Patent Application Publication
(10) Pub. No.: US 2019/0361631 A1
(43) Pub. Date: Nov. 28, 2019

(54) STORAGE DEVICE, CHIP AND METHOD FOR CONTROLLING STORAGE DEVICE

(71) Applicant: SZ DJI TECHNOLOGY CO., LTD., Shenzhen (CN)

(72) Inventors: Kang YANG, Shenzhen (CN); Mingming GAO, Shenzhen (CN)

(21) Appl. No.: 16/538,137

(22) Filed: Aug. 12, 2019

Related U.S. Application Data
(63) Continuation of application No. PCT/CN2017/073849, filed on Feb. 17, 2017.

(51) Int. Cl. G06F 3/06; G11C 11/419; G11C 11/417; G11C 11/418

(52) U.S. Cl. CPC G06F 3/0659; G06F 3/0604; G11C 11/418; G11C 11/419; G11C 11/417; G06F 3/0673

(57) ABSTRACT

A storage device includes a single-port random access memory (RAM), a buffer circuit, a read port connected to the single-port RAM, a write port connected to the single-port RAM through the buffer circuit, and a control circuit. The control circuit is configured to, in a clock cycle, write a first data block inputted from the write port into the buffer circuit, retrieve a second data block from stored data, and send the second data block to the read port.

### CROSS REFERENCE TO RELATED APPLICATION

This application is a continuation of International Application No. PCT/CN2017/073849, filed on Feb. 17, 2017, the entire content of which is incorporated herein by reference.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The present disclosure relates to the field of data storage electronic and, more particularly, to a storage device, a chip, and a method for controlling the storage device.

### BACKGROUND

Typical integrated circuits include field programmable gate arrays (FPGA), application specific integrated circuits (ASIC), etc.

In many application scenarios, an integrated circuit system (hereinafter referred to as a system) is required to support a high efficiency for accessing memory and simultaneous reading and writing of data in the memory. To support simultaneous reading and writing of data, system designers often choose a dual-port random access memory (RAM) as a main storage device of the system. However, the dual-port RAM is bulky, increasing a size and power consumption of the system.

### SUMMARY

In accordance with the disclosure, there is provided a storage device including a single-port random access memory (RAM), a buffer circuit, a read port connected to the single-port RAM, a write port connected to the single-port RAM through the buffer circuit, and a control circuit. The control circuit is configured to, in a clock cycle, write a first data block inputted from the write port into the buffer circuit, retrieve a second data block from stored data, and send the second data block to the read port.

Also in accordance with the disclosure, there is provided a chip including a storage device and an access device connected to the storage device. The storage device includes a single-port RAM, a buffer circuit, a read port connected to the single-port RAM, a write port connected to the single-port RAM through the buffer circuit, and a control circuit. The control circuit is configured to, in a clock cycle, write a first data block inputted from the write port into the buffer circuit, retrieve a second data block from stored data, and send the second data block to the read port. The access memory is configured to access the storage device through the read port and the write port.

Also in accordance with the disclosure, there is provided a method for controlling a storage device including, in a clock cycle, writing a first data block inputted from a write port of the storage device into a buffer circuit of the storage device, retrieving a second data block from stored data, and sending the second data block to a read port of the storage device. The write port is connected to a single-port RAM of the storage device through the buffer circuit, and the read port is connected to the single-port RAM.

### BRIEF DESCRIPTION OF THE DRAWINGS

FIG. 1 is a schematic structural diagram of a storage device according to an example embodiment.

FIG. 2 is a schematic structural diagram of a storage device according to another example embodiment.

FIG. 3 is a schematic structural diagram of a storage device according to another example embodiment.

FIG. 4 is a schematic structural diagram of a storage device according to another example embodiment.

FIG. 5 is a schematic structural diagram of a chip according to an example embodiment.

FIG. 6 is an illustrative flowchart of a method for controlling the storage device according to an example embodiment.

### DETAILED DESCRIPTION OF THE EMBODIMENTS

Technical solutions of the present disclosure will be described with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

It should be noted that, in some embodiments, when one component is “fixedly connected” or “connected” to another component, or one component is “fixed” to another component, the component may directly contact the another component, or may not directly contact the another component and may have something in-between.

Unless otherwise specified, all the technical and scientific terms used in the embodiments of the present disclosure refer to the same meaning commonly understood by those skilled in the art. The terminologies used in the present disclosure are intended to describe specific embodiments, and not to limit the scope of the present disclosure. The term “and/or” includes any and all combinations of one or more of the listed items.

A dual-port random access memory (RAM) includes two sets of data lines and address lines to support simultaneous reading and writing of data. However, the size of the dual-port RAM is often twice or three times of a size of a single-port RAM having a comparable capacity. The size and power consumption of the system often depend on the size of the RAM. Thus, the dual-port RAM based system has the disadvantages of large size and high power consumption.

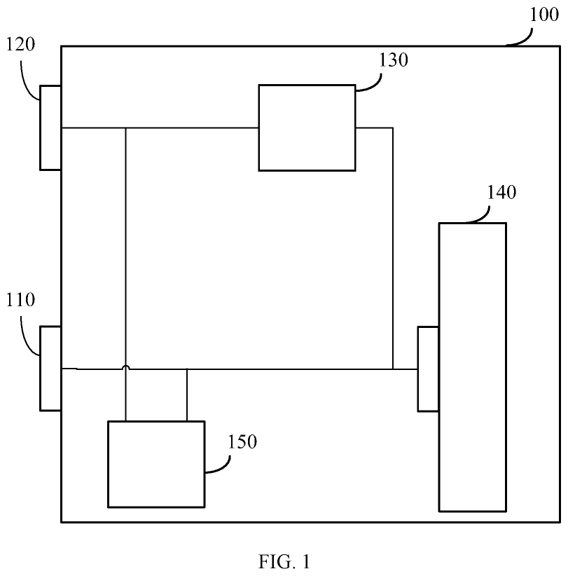

To reduce the size and power consumption of the system, the present disclosure provides a solution based on the single-port RAM. The single-port RMA includes one port. Because one port corresponds to one set of data lines and address lines, the single-port RAM is unable to support simultaneous reading and writing of data. To enable simultaneous reading and writing of data in the solution based on the single-port RAM, the present disclosure expands the solution based on the single-port RAM. A storage device provided by the embodiments of the present disclosure will be described in detail below with reference to FIG. 1.

FIG. 1 is a schematic structural diagram of a storage device according to disclosed embodiments of the present disclosure. As shown in FIG. 1, the storage device 100 includes a read port 110, a write port 120, a buffer circuit 130, a single-port RAM 140 (hereinafter abbreviated as RAM 140), a control circuit 150. The read port 110 is connected to the RAM 140. The write port 120 is connected to the RAM 140 through the buffer circuit 130.

The control circuit 150 is configured to write a first data block inputted from the write port 120 to the buffer circuit 130 in the nth clock cycle. n is a positive integer greater than or equal to 1. Further, in the nth clock cycle, the control circuit 150 can also retrieve a second data block from stored data and send the second data block to the read port 110.

The present disclosure provides a solution to replace the dual-port RAM with the single-port RAM. Compared to the dual-port RAM, the single-port RAM has the advantages of small size and low power consumption. Further, the present disclosure enhances the solution based on the single-port RAM to include the buffer circuit between the signal-port RAM and the write port of the storage device, such that the solution based on the single-port RAM is able to support simultaneous reading and writing of data. Thus, the solution according to the present disclosure provides small size and low power consumption of the system while supporting simultaneous reading and writing of data.

The present disclosure does not limit the application scenarios for the storage device 100. In some embodiments, the storage device 100 may be configured to simulate the dual-port RAM. The dual-port RAM may be a simple dual-port RAM (also referred to as a “pseudo dual-port RAM”) or a true dual-port RAM. In some other embodiments, the storage device 100 may be configured to simulate a first-in-first-out (FIFO) queue.

The present disclosure does not limit the specific form of the buffer circuit 130. In some embodiments, the buffer circuit 130 may include one or more buffers. In some other embodiments, the buffer circuit 130 may include one or more register sets. Assuming that the buffer circuit 130 includes a plurality of register sets, the plurality of register sets may sequentially (or alternately) store the data blocks inputted from the write port 120.

In some embodiments, the RAM 140 may be a static random access memory (SRAM).

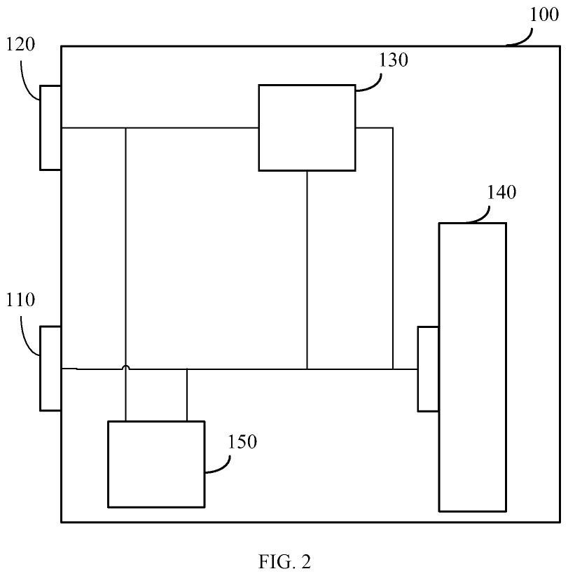

In the nth clock cycle, the control circuit 150 may retrieve the second data block from the stored data. The method of retrieving the second data block is not limited by the present disclosure. In some embodiments, the control circuit 150 may retrieve the second data block from the RAM 140. In some other embodiments, considering that all the data blocks to be written into the RAM 140 will be first written to the buffer circuit 130, the control circuit 150 may retrieve the second data block either from the RAM 140 or from the buffer circuit 130 if the data block in the buffer circuit 130 has not been overwritten. This implementation will be described in detail below with reference to FIG. 2.

FIG. 2 is a schematic structural diagram of a storage device according to disclosed embodiments of the present disclosure. As shown in FIG. 2, the read port 110 is connected to not only the RAM 140, but also the buffer circuit 130. Retrieving the second data block from the stored data by the control circuit 150 includes the following process. Based on the read address of the second data block and an address range of data blocks stored in the buffer circuit 130, the control circuit 150 determines whether the buffer circuit 130 stores the second data block. If the buffer circuit 130 does not store the second data block, the control circuit 150 retrieves the second data block from the RAM 140. Further, in some embodiments, the control circuit 150 may also be configured to retrieve the second data block from the buffer circuit 130 if the buffer circuit 130 includes the second data block.

In some embodiments, if the data block to be retrieved is stored in the buffer circuit 130, the data block will be retrieved from the buffer circuit 130. As such, a number of times of accessing the RAM 140 may be effectively reduced. Because the power consumption of the storage device mainly depends on the power consumption of the RAM, reducing the number of times of accessing the RAM means reducing the power consumption of the storage device. For example, in a scenario that the storage device is used to simulate a FIFO queue, if a difference between the read address and the write address of the data block is relatively small, a probability of retrieving the data block from the buffer circuit 130 is relatively large. Thus, the power consumption of the storage device may be maintained at a relatively low level.

In some embodiments, every time the write port 120 writes a new data block to the buffer circuit 130, the address range of the data blocks stored in the buffer circuit 130 may be updated according to the write address of the new data block. In response to a read instruction for the second data block received through the read port 110, the control circuit 150 may determine whether the read address of the second data block falls in the address range of the data blocks stored in the buffer circuit 130. If the read address of the second data block falls in the address range, it is determined that the second data block is still stored in the buffer circuit 130 (i.e., has not been overwritten by a subsequent data block). As such, the control circuit 150 may retrieve the second data block from the buffer circuit 130. If the read address of the second data block does not fall in the address range, it is determined that the second data block stored in the buffer circuit 130 has been overwritten. As such, the control circuit 150 may retrieve the second data block from the RAM 140.

In some embodiments, the address range of the data blocks stored in the buffer circuit 130 may be tracked by maintaining a starting address pointer and an ending address pointer of each buffer (or register set) in the buffer circuit 130. In some embodiments, the address range of the data block stored in a buffer (or register set) can be a difference between the starting address pointer and the ending address pointer of the buffer (or register set).

In some embodiments, the control circuit 150 may be configured to, in the (n+k)th clock cycle, write the first data block into the RAM 140. The (n+k)th clock cycle is a clock cycle in which the RAM 140 is not required to perform a read operation. k is an integer greater than or equal to 1.

The (n+k)th clock cycle may be any clock cycle in which there is no read operation performed at the port of the RAM 140. In some embodiments, the buffer circuit 130 may be considered as a cache or a temporary storage area where the data block to be written into the RAM 140 is temporarily stored. When the port of the RAM 140 is idle, the data block stored in the buffer 130 may be written into the RAM 140. In the embodiments of the present disclosure, the cache is configured to avoid occurrences of read and write collision at the single port of the RAM 140.

Further, in some embodiments, both the read port 110 and the write port 120 have a bit-width of N. The port of the RAM 140 has a bit-width of K×N, where N is an integer greater than or equal to 1 and K is an integer greater than 1. Writing the first data block into the RAM 140 may include retrieving target data from the buffer circuit 130 and writing the target data into the RAM 140 at once. The target data includes K data blocks. The first data block is one of the K data blocks.

For illustrative purposes, the bit-width of the RAM 140 is set to be twice of the bit-width of the port (the read port 110 or the write port 120) of the storage device 100. Assume that an external memory accessing device writes 10 data blocks into the buffer circuit 130 in 10 clock cycles, then because the bit-width of the port of the RAM 140 is twice of the bit-width of the write port 120, it only takes 5 clock cycles to write the 10 data blocks into the RAM 140, thereby saving one half of the clock cycles. In other words, the RAM 140 is idle in one half of the clock cycles. The read operations may be performed in the idle clock cycles, such that the storage device 100 may perform simultaneous and continuous read and write operations.

In some embodiments, the buffer circuit 130 may include K register sets of a same depth. Each of the K register sets has a bit-width of N. The K register sets may sequentially (or alternately) store the data blocks written through the write port 120. As such, when the data block is required to be written into the RAM 140, one data block may be retrieved from each of the K the register sets to obtain K data blocks. Then, the K data blocks are concatenated to generate the target data. The target data may be written into the RAM 140 in one write operation.

Further, in some embodiments, the ith data block in the K data blocks is stored in the buffer circuit 130 earlier than the (i+1)th data block in the K data blocks, where 1≤i≤K−1. The control circuit 150 is configured to, in the (n+k+t)th clock cycle, determine a target address of the target data in the RAM 140 based on the read address of the first data block. The target address is equal to the quotient of the read address of the first data block divided by K. t is an integer greater than or equal to 1. The control circuit 150 retrieves the target data from the target address. Based on the read address of the target data, the control circuit 150 obtains the mth data block in the K data blocks from the target data as the first data block. m is equal to the remainder of the read address of the first data block divided by K.

Because the bit-width of the port of the RAM 140 is K times the bit-width of the write port 120, the first through Kth data blocks inputted from the write port 120 to the buffer circuit 130 may be concatenated according to the time sequence they are written into the buffer circuit 130. The concatenated data may be written into the starting address of the RAM 140 in one write operation. Similarly, the (K+1)th through 2 Kth data blocks inputted from the write port 120 to the buffer circuit 130 may be concatenated according to the time sequence they are written into the buffer circuit 130. The concatenated data may be written into an address following the staring address of the RAM 140 in one write operation. The same process may be repeated.

After the data are stored in the above described process, a fixed mapping relationship may be formed between the read address of the data blocks and the storage address of the data blocks in the RAM 140. The quotient of the read address of the data blocks divided by K is the storage address of the data blocks in the RAM 140. The remainder m of the read address of the data blocks divided by K indicates that the data block is the mth data block of the data stored at the storage address (the data stored at the each storage address of the RAM 140 include K number of the data blocks). The above described implementation may form the fixed relationship between the read address of the data blocks and the storage address of the data blocks in the RAM 140, thereby simplifying the retrieval process of the data blocks.

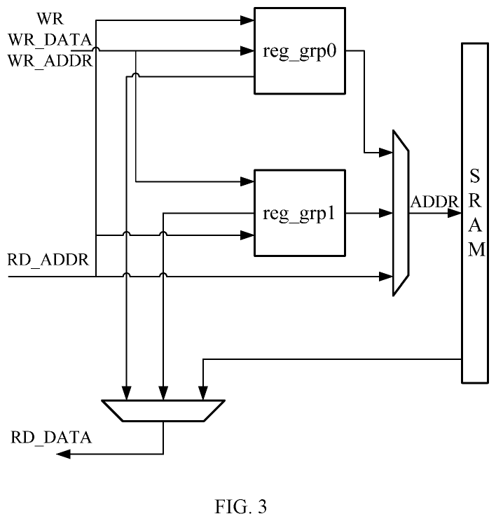

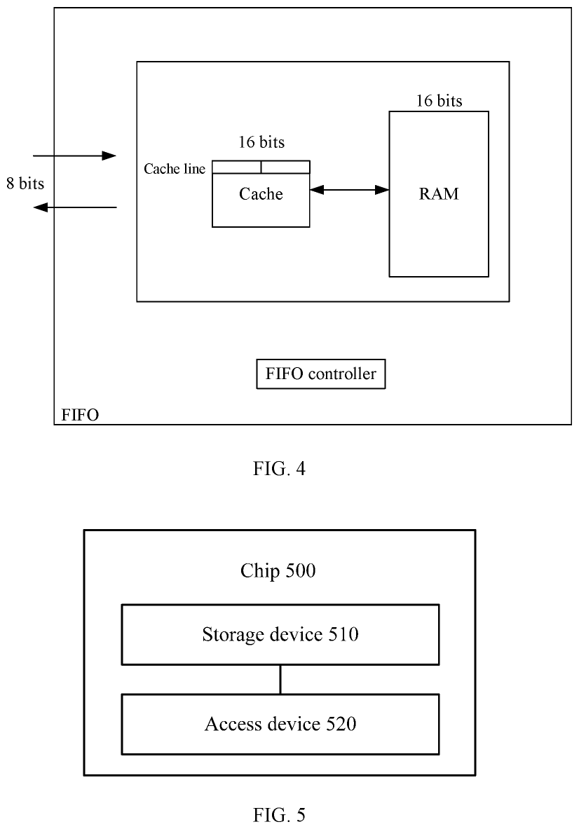

The embodiments of the present disclosure will be described in more details with reference to specific examples. The examples shown in FIG. 3 and FIG. 4 are intended to assist those skilled in the art to comprehend the embodiments of the present disclosure. The present disclosure is not limited by the specific numbers or application scenarios illustrated in FIG. 3 and FIG. 4. Those skilled in the art may make various modifications and changes based on the examples shown in FIG. 3 and FIG. 4. Such modifications and changes are within the scope of the embodiments of the present disclosure.

FIG. 3 is a schematic structural diagram of a storage device according to disclosed embodiments of the present disclosure. As shown in FIG. 3, the buffer circuit of the storage device includes a register set reg_grp0 and a register set reg_grp1. The single-port RAM in the storage device is an SRAM. The storage device further includes a data line WR_DATA and an address line WR_ADDR corresponding to the write port (not shown in FIG. 3), a data line RD_DATA and an address line RD_ADDR corresponding to the read port (not shown in FIG. 3), and an address line ADDR corresponding to the port of the SRAM. The control circuit (not shown in FIG. 3) controls the modules or circuits shown in FIG. 3 to perform read and write operations of the data according to certain control logics. The read and write operations of the storage device in FIG. 3 will be described in detail below.

In the embodiments described below, the bit-width of the read port and the write port of the storage device shown in FIG. 3 is assumed to be 8 bits. The bit-width and depth of the register sets reg_grp0 and the reg_grp1 are 8 bits and 8, respectively. The SRAM is a single-port RAM. The bit-width and depth of the SRAM are 16 bits and 1024, respectively. The bit-width and depth of the register sets reg_grp0 and reg_grp1, and SRAM may be determined according actual application scenarios. The numbers given are merely exemplary.

When WR signal is valid (e.g., WR signal is high), the data blocks inputted from the write port are sequentially (or alternately) written into the register sets reg_grp0 and reg_grp1. For example, if WR_ADDR[0]=(WR_ADDR[0] represents a lowest address bit of a write address), the data block inputted from the write port is written into the register set reg_grp0. If WR_ADDR[0]=1, the data block inputted from the write port is written into the register set reg_grp1.

After the data block is written into the register set reg_grp1, if there is no read operation performed on the SRAM in a certain clock cycle, the data blocks written into the register sets reg_grp0 and reg_grp1 may be retrieved in the clock cycle and concatenated to generate the 16-bit wide target data. The 16-bit target data may be written into the SRAM in one write operation.

If the last write operation happens to write the data block into the register set reg_grp0, the data blocks in the register sets reg_grp0 and the reg_grp1 may be directly written into the SRAM without waiting for a new data block to be stored into the register set reg_ grp1.

When the read port receives a read instruction, the read address of the to-be-retrieved data block (hereinafter referred to as data block 1) and the address range of the data block recorded by the register sets reg_grp0 and/or reg_grp1 may be used to determine whether the data block 1 is still stored in the register set reg_grp0 or reg_grp1 without being overwritten. If the data block 1 is still stored in the register set reg_grp0 or reg_grp1, the data block 1 may be retrieved from the register set reg_grp0 or reg_grp1, such that the number of times of accessing the SRAM may be reduced and the power consumption of the storage device may be reduced.

For example, the data block with the lowest bit of the write address (WR_ADDR[0]) being 0 may be stored in the register set reg_grp0, and the data block with the lowest bit of the write address (WR_ADDR[0]) being 1 may be stored in the register set reg_grp1. When the read operation needs to be performed, the read address of the data block 1 may be obtained first. If the lowest bit of the read address of the data block 1 is 0, the data block 1 may be looked up in the register set reg_grp0. If the lowest bit of the read address of the data block 1 is 1, the data block 1 may be looked up in the register set reg_grp1.

Taking the lowest bit of the read address of the data block 1 being 0 as an example, the address range of the data block recorded by the register set reg_grp0 can be looked up. If the read address of the data block 1 falls in the address range, it is determined that the data block 1 is still stored in the register set reg_grp0 without being overwritten. In this case, the data block 1 may be retrieved from the register set reg_grp0. In the above, the lowest bit of the read address of the data block 1 is used to determine which register set stores the data block 1. The present disclosure is not limited thereto. For example, the highest bit of the read address of the data block 1 may be used to determine which register set stores the data block 1.

Further, if the data block 1 is not stored in the register set reg_grp0 or reg_grp1, the data block 1 may be retrieved from the SRAM. Because the bit-width of the read and write port of the storage device is one half of the bit-width of the port of the SRAM, the read address of the data block 1 is divided by 2 to obtain the quotient and the reminder. The quotient is the storage address of the data block 1 in the SRAM. If the remainder is 1, the data block 1 is the first 8 bits of the 16-bit data stored at the storage address. If the remainder is 0, the data block 1 is the last 8 bits of the 16-bit data stored at the storage address.

Because the bit-width of the read and write port of the storage device is one half of the bit-width of the port of the SRAM, the write speed of the SRAM is 50% of the write speed of the write port. If the storage device writes 8×X bits of data through the write port in X consecutive clock cycles, only X/2 clock cycles are required to write the 8×X bits of data into the SRAM. The remaining X/2 clock cycles may be used to perform read operations. As such, the storage device provided by the embodiments of the present disclosure may simultaneously read and write data even if the write port is in a continuous write state.

The storage device provided by the embodiments of the present disclosure may be used to implement a FIFO or a FIFO-like data storage. FIG. 4 is a schematic structural diagram of a storage device according to disclosed embodiments of the present disclosure. The storage device in FIG. 4 may be used to implement the FIFO. As shown in FIG. 4, the bit-widths of the read and write ports (not shown) are both 8 bits. The buffer circuit of the storage device includes a cache. The size of each cache line is 16 bits, capable of storing two 8-bit data blocks inputted from the write port.

For illustrative purposes, the buffer circuit includes one cache. But the present disclosure is not limited to this configuration. The buffer circuit of the storage device may include a plurality of caches. For example, the buffer circuit may include two caches. Cache lines in each cache are able to store 8-bit data.

Further, the depth of the cache and the RAM may be determined according to the practical applications and is not limited by the present disclosure. For example, the depth of the cache may be 8, and the depth of the RAM may be 1,024.

To implement (or simulate) the FIFO, both the cache and the RAM may be controlled by the control circuit (i.e., the FIFO controller in FIG. 4) to store data in the first-in-first-out manner. In some embodiment, the first 8-bit data block inputted from the write port may be written to the high 8-bit of the first cache line, the second 8-bit data inputted from the write port may be written to the low 8-bit of the first cache line. So on so forth.

In the process of writing the data blocks to the cache, the FIFO controller may monitor whether the port of the RAM performs any read operation. If the port of the RAM does not perform any read operation, the 16-bit data block (including the first 8-bit data block and the second 8-bit data block) stored in the first cache line is written to the first address of the RAM. The 16-bit data block stored in the second cache line is written to the next address following the first address of the RAM. So on so forth. Eventually, the each 8-bit data block inputted from the write port may be sequentially written into the RAM. However, because the bit-width of the port of the RAM is 16 bits, the quotient of the write address of each 8-bit data block divided by 2 is the storage address of the 8-bit data block in the RAM. The remainder 0 represents that the 8-bit data block is the lowest 8 bits stored at the storage address of the RAM. The remainder 1 represents that the 8-bit data block is the highest 8 bits stored at the storage address of the RAM. Subsequently, the address mapping relationship may be used to retrieve the data.

In the process of storing the data blocks, if the read instruction for the first 8-bit data block is received by the read port, the FIFO controller may first query the address range of the data blocks stored in the cache to determine whether the first 8-bit data block is still stored in the cache (due to the limited depth of the cache, the data blocks stored in the case may be overwritten). If the first 8-bit data block is still stored in the cache, the FIFO controller may retrieve the first 8-bit data block from the cache. If the first 8-bit data block is no longer stored in the cache, the FIFO controller may use the address mapping relationship to retrieve the 16-bit data block from the RAM and to retrieve the 8-bit data block from the 16-bit data block.

For example, based on the address mapping relationship, the first 8-bit data block is the highest 8 bits stored at the first address of the RAM. After the FIFO controller outputs the 8-bit data bock stored in the highest 8 bits at the first address of the RAM, the process of retrieving the first 8-bit data block is completed. The retrieval of the second 8-bit data block, the third 8-bit data block, and the subsequent 8-bit data blocks may be similar and will not be described in detail herein.

As such, in the embodiments of the present disclosure, the FIFO is implemented by the cache and the single-port RAM. Because the single-port RAM has the advantage of small size, the power consumption of the FIFO may be substantially reduced.

FIG. 5 is a schematic structural diagram of a chip 500 according to disclosed embodiments of the present disclosure. As shown in FIG. 5, the chip 500 includes a storage device 510 and an access device 520. The storage device 510 may be any of the storage device shown in FIGS. 1-4. The access device 520 is connected to the storage device 510. The access device 520 accesses the storage device 510 through the read port and the write port of the storage device 510.

In the embodiments of the present disclosure, the single-port RAM solution replaces the dual-port RAM solution. Compared to the dual-port RAM, the single-port RAM has the advantages of small size and low power consumption. Further, the embodiments of the present disclosure enhances the single-port solution to include the buffer circuit (compared to the RAM, the buffer circuit often has small size and low power consumption) disposed between the single-port RAM and the write port of the storage device. As such, the single-port RAM can support simultaneous reading and writing of data. Thus, the technical solution provided by the embodiments of the present disclosure reduces the size and power consumption of the system at the same time the simultaneous reading and writing of data is supported.

The present disclosure does not limit the type of the chip. The chip may be an FPGA or an ASIC.

The present disclosure also provides a method for controlling the storage device. Because the method is performed by the control circuit in the storage device, previously described embodiments of the present disclosure may be referred to for the description about other parts of the storage device.

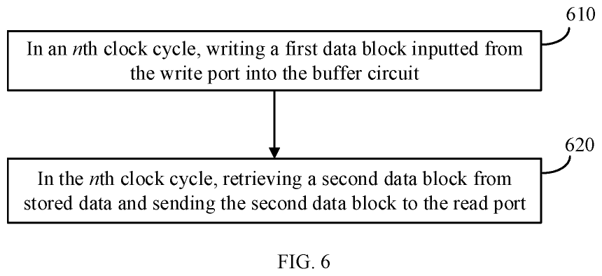

FIG. 6 is an illustrative flowchart of a method for controlling the storage device according to disclosed embodiments of the present disclosure. As shown in FIG. 6, the storage device includes a read port, a write port, a buffer circuit, and a single-port RAM. The read port is connected to the single-port RAM. The write port is also connected to the single-port RAM. As shown in FIG. 6, the method may include the following process.

At 610, a first data block inputted from the write port is written into the buffer circuit in the nth clock cycle.

At 620, a second data block is retrieved from stored data and sent to the read port in the nth clock cycle.

In the embodiments of the present disclosure, a solution based on the single-port RAM replaces the solution based on the dual-port RAM. Compared to the dual-port RAM, the single-port RAM has the advantages of small size and low power consumption. Further, the embodiments of the present disclosure enhance the solution based on the single-port RAM to include the buffer circuit (compared to the RAM, the buffer circuit has substantially small size and substantially low power consumption) disposed between the single-port RAM and the write port of the storage device. As such, the single-port RAM can support simultaneous reading and writing of data. Thus, the technical solution provided by the embodiments of the present disclosure reduces the size and power consumption of the system at the same time the simultaneous reading and writing of data is supported.

In some embodiments, the method further includes: in the (n+k)th clock cycle, the first data block is written into the RAM, where the (n+k)th clock cycle is a clock cycle in which no read operation is performed, and k is an integer greater than or equal to 1.

In some embodiments, the bit-widths of both the read port and the write port are N. The bit-width of the port of the RAM is K×N, where N is an integer greater than or equal to 1 and K is an integer greater than 1. Writing the first data block into the RAM includes: retrieving target data including K the data blocks from the buffer circuit where the first data block is one of the K number of the data blocks; and writing the target data into the RAM in one write operation.

In some embodiments, the ith data block in the K data blocks is stored in the buffer circuit earlier than the (i+l)th data block of the K data blocks, where 1≤i≤K−1. The method in FIG. 6 may further include: in the (n+k+t)th clock cycle, determining a target address of the target data in the RAM based on the read address of the first data block, where the target address is equal to the quotient of the read address of the first data block divided by K and t is an integer greater than or equal to 1; retrieving the target data at the target address; and based on the read address of the target data, obtaining the mth data block in the K data blocks from the target data as the first data block, where m is equal to the remainder of the read address of the first data block divided by K.

In some embodiments, the buffer circuit may include K register sets. The K register sets may sequentially (or alternately) store the data blocks inputted from the write port.

In some embodiments, the read port is connected to the buffer circuit. Process at 620 may include: based on the read address of the second data block and the address range of the data blocks stored in the buffer circuit, determining whether the buffer circuit stores the second data block; and if the buffer circuit does not store the second data block, retrieving the second data block from the RAM.

In some embodiments, the method in FIG. 6 may further include: retrieving the second data block from the buffer circuit if the buffer circuit stores the second data block.

The embodiments of the present disclosure may be implemented entirely or partially by software, hardware, firmware, or any combination thereof. When implemented in software, the embodiments of the present disclosure may be implemented entirely or partially in the form of a computer program product. The computer program product may include one or more computer program instructions. Executing the computer program instructions on a computer may entirely or partially produce the flow chart process or functions according to the embodiments of the present disclosure. The computer may be a general-purpose computer, a specialized computer, a computer network, or other programmable devices. The computer program instructions may be stored in a computer readable storage medium or may be transferred from one computer readable storage medium to another computer readable storage medium. For example, the computer program instructions may be transferred from one network node, one computer, one server, or one data center to another network node, another computer, another server, or another data center through a wired (e.g., coaxial cable, optical fiber, digital subscriber line) or wireless (e.g., infrared, radio, microwave, etc.) communication method. The computer readable storage medium may include any computer accessible usable medium or one or more of data storage equipment such as usable medium integrated servers or data centers. The usable medium may include a magnetic medium (e.g., a floppy disk, a hard disk, a magnetic tape), or a semiconductor medium (e.g., solid state disk), etc.

The phrase “one embodiment,” “some embodiments,” or “other embodiments” in the specification means that the particular features, structures, or characteristics related to the embodiments are included in at least one embodiment of the present disclosure. Thus, they are not intended to be the same embodiment. In addition, these particular features, structures, or characteristics may be combined in any suitable manner in one or more embodiments.

In various embodiments of the present disclosure, sequence numbers of the processes have nothing to do with the order of execution sequence. Instead, the order of executing the processes should be determined by functions and intrinsic logics. The sequence numbers should not limit the implementation of the embodiments of the present disclosure.

In various embodiments of the present disclosure, the phrase “B corresponding to A” can mean that B is associated with A and/or B can be determined according to A. However, determining B from A does not mean that B is determined only based on A, but B can be determined based on A and/or other information.

The term “and/or” herein is merely an association relationship describing associated objects, representing three relationships. For example, A and/or B may represent an existence of A only, an existence of B only, and a co-existence of both A and B. In addition, the character “/” in the specification generally represents that the associated objects have an “or” relationship.

Those skilled in the art will appreciate that the elements and algorithm steps described in various embodiments of the present disclosure can be implemented in electronic hardware or a combination of computer software and electronic hardware. Whether a function is implemented in hardware or software may be determined by specific application and design constraints of the particular solution. Those skilled in the art may use different methods to implement a function described in the specification depending on each specific application. However, such implementation should not be considered to be beyond the scope of the present disclosure.

Those skilled in the art may clearly understand that, for convenience and brevity, detailed operation process of systems, devices and sub-systems may refer to corresponding process previously described in the embodiments and may not be repeated.

In the embodiments of the present disclosure, the disclosed systems, devices and methods may be implemented in other manners. For example, the device embodiments described above are merely illustrative. For example, the division of sub-systems may be only a logical function division. In practical applications, sub-systems may be divided differently. For example, multiple sub-systems or components may be combined or integrated into another system. Certain features may be omitted or not executed. Further, mutual coupling, direct coupling, or communication connection shown or discussed may be implemented by certain interfaces. Indirect coupling or communication connection of devices or sub-systems may be electrical, mechanical, or in other forms.

Sub-systems described as separated components may or may not be physically separated. A sub-system shown as a separate component may or may not be a physically separated sub-system. That is, the sub-system may be located in one place or may be distributed in multiple network elements. According to practical applications, all or a portion of sub-systems may be implemented to achieve the objectives of the embodiments of the present disclosure.

In addition, functional sub-systems described in different embodiments of the present disclosure may be integrated into one processing sub-system or may exist physically separately. Two or more sub-systems may be integrated into one sub-system.

The foregoing descriptions are merely some implementation manners of the present disclosure, but the scope of the present disclosure is not limited thereto. Any change or replacement that can be conceived by a person skilled in the art based on the technical scope disclosed by the present application should be covered by the scope of the present disclosure. A true scope and spirit of the invention is indicated by the following claims.

What is claimed is:

1. A storage device comprising:
a single-port random access memory (RAM);
a buffer circuit;
a read port connected to the single-port RAM;
a write port connected to the single-port RAM through the buffer circuit; and
a control circuit configured to, in a clock cycle:
write a first data block inputted from the write port into the buffer circuit; and
retrieve a second data block from stored data and send the second data block to the read port.

2. The storage device of claim 1, wherein:
the clock cycle is a first clock cycle; and
the control circuit is further configured to:
in a second clock cycle, which is after the first clock cycle and in which no read operation is performed to the single-port RAM, write the first data block into the single-port RAM.

3. The storage device of claim 2, wherein:
a bit-width of the read port and a bit-width of the write port both equal N, N being an integer greater than or equal to 1;
a bit-width of a port of the single-port RAM is K×N, K being an integer greater than 1; and
the control circuit is configured to write the first data block into the single-port RAM by:
retrieving target data including K data blocks from the buffer circuit, the first data block being one of the K data blocks; and
writing the target data into the single-port RAM in one write operation.

4. The storage device of claim 3, wherein the control circuit is further configured to:
in a third clock cycle after the second clock cycle, determine a target address of the target data in the single-port RAM to be a quotient of a read address of the first data block divided by K;
retrieve the target data from the target address; and
retrieve an mth data block of the K data blocks from the target data as the first data block, m being a remainder of the read address of the first data block divided by K.

5. The storage device of claim 1, wherein:
the buffer circuit includes K register sets, K being an integer greater than 1; and
the K register sets are configured to sequentially store data blocks inputted from the write port.

6. The storage device of claim 1, wherein:
the read port is connected to the buffer circuit; and
the control circuit is configured to retrieve the second data block from the stored data by:
determining whether the buffer circuit stores the second data block based on a read address of the second data block and an address range of the data blocks stored in the buffer circuit; and
in response to the buffer circuit not storing the second data block, retrieving the second data block from the single-port RAM.

7. The storage device of claim 6, wherein the control circuit is further configured to:
in response to the buffer circuit storing the second data block, retrieve the second data block from the buffer circuit.

8. A chip comprising:
a storage device including:
a single-port random access memory (RAM);
a buffer circuit;
a read port connected to the single-port RAM;
a write port connected to the single-port RAM through the buffer circuit; and
a control circuit configured to, in a clock cycle:
write a first data block inputted from the write port into the buffer circuit; and
retrieve a second data block from stored data and send the second data block to the read port; and
an access device connected to the storage device and configured to access the storage device through the read port and the write port.

9. The chip of claim 8, wherein:
the chip is a field programmable gate array or an application specific integrated circuit.

10. A method for controlling a storage device comprising, in a clock cycle:
writing a first data block inputted from a write port of the storage device into a buffer circuit of the storage device, the write port being connected to a single-port random access memory (RAM) of the storage device through the buffer circuit; and
retrieving a second data block from stored data and sending the second data block to a read port of the storage device, the read port being connected to the single-port RAM.

11. The method of claim 10,
wherein the clock cycle is a first clock cycle;
the method further comprising:
in a second clock cycle, which is after the first clock cycle and in which no read operation is performed to the single-port RAM, writing the first data block into the single-port RAM.

12. The method of claim 11, wherein:
a bit-width of the read port and a bit-width of the write port both equal N, N being an integer greater than or equal to 1;
a bit-width of a port of the single-port RAM is K×N, K being an integer greater than 1; and
writing the first data block into the single-port RAM includes:
retrieving target data including K data blocks from the buffer circuit, the first data block being one of the K data blocks; and
writing the target data into the single-port RAM in one write operation.

13. The method of claim 12, further comprising:
in a third clock cycle after the second clock cycle, determining a target address of the target data in the single-port RAM to be a quotient of a read address of the first data block divided by K;
retrieving the target data at the target address; and
retrieving an mth data block of the K data blocks from the target data as the first data block, m being a remainder of the read address of the first data block divided by K.

14. The method of claim 10, wherein:
the buffer circuit includes K register sets, K being an integer greater than 1; and
the K register sets are configured to sequentially store data blocks inputted from the write port.

15. The method of claim 10, wherein:
the read port is connected to the buffer circuit; and
retrieving the second data block from the stored data includes:
determining whether the buffer circuit stores the second data block based on a read address of the second data block and an address range of the data blocks stored in the buffer circuit; and
in response to the buffer circuit not storing the second data block, retrieving the second data block from the single-port RAM.

16. The method of claim 15, further comprising:
in response to the buffer circuit storing the second data block, retrieving the second data block from the buffer circuit.
